(19) United States
(12) Patent Application Publication
(10) Pub. No.: US 2004/0038502 A1
(43) Pub. Date: Feb. 26, 2004

(54) Method of detecting chemical mechanical polishing endpoints in thin film head processes

(76) Inventors: Sethuraman Jayashankar, Pittsburgh, PA (US); Earl C. Johns, Sewickley, PA (US)

Correspondence Address: Robert P. Lenart, Pietragallo, Bosick & Gordon, One Oxford Centre, 38th Floor, 301 Grant Street, Pittsburgh, PA, 15219, US

(21) Appl. No.: 10/603,389

(22) Filed: Jun. 25, 2003

Related U.S. Application Data
(60) Provisional application No. 60/391,760, filed on Jun. 26, 2002.

(51) Int. Cl. H01L 21/20

(52) U.S. Cl. 438/489

(57) ABSTRACT

A method of chemical mechanical polishing a wafer comprises: forming an optical property modifying layer on a surface of a feature of interest disposed on a wafer, removing material from the wafer using a chemical mechanical polishing process, directing light onto a surface of the wafer and using light reflected from a surface of the wafer to determine when the optical property modifying layer has been reached, and stopping the chemical mechanical polishing process in response to the determination that the optical property modifying layer has been reached. A wafer for use in manufacturing a magnetic recording head is also included. The wafer comprises a substrate, a pattern including an optical property modifying layer on a surface of a feature of interest supported by the substrate, and a dielectric layer positioned on the optical property modifying layer.

### CROSS REFERENCE TO RELATED APPLICATION

This application claims the benefit of U.S. Provisional Patent Application Serial No. 60/391,760, filed Jun. 26, 2002, the disclosure of which is hereby incorporated by reference.

### FIELD OF THE INVENTION

This invention relates to chemical mechanical polishing (CMP) processes, and more particularly to methods for detecting endpoints in CMP processes.

### BACKGROUND OF THE INVENTION

Chemical mechanical polishing is a widely used technique for planarizing various electronic device structures. CMP processes typically involve holding and rotating a thin, flat wafer against a wetted polishing surface under controlled chemical, pressure, and temperature conditions. A chemical slurry containing a polishing agent, such as alumina or silica, can be used as the abrasive material. Additionally, the chemical slurry can contain selected chemicals which etch various surfaces of the wafer during processing. The combination of mechanical and chemical removal of material during polishing results in superior planarization of the polished surface. It is important to remove a sufficient amount of material to provide a smooth surface, without removing an excessive amount of underlying material. In many instances, such as when dealing with very thin structures, detection of the process endpoint is critical to correctly stopping CMP planarization processes at the right thickness.

Numerous techniques have been proposed to detect the endpoint in CMP processes. For example, the endpoint has been detected by interrupting the CMP process, removing the wafer from the polishing apparatus, and physically examining the wafer surface by techniques which ascertain film thickness and/or surface topography. If the wafer does not meet specifications, it must be loaded back into the polishing apparatus for further planarization. If excess material has been removed, the wafer may not meet specifications and will be substandard.

In other endpoint detection techniques, changes in electric current supplied to a motor that rotates the wafer and/or polishing surface, and/or changes in the intensity of an optical signal reflected from the wafer have been used to detect the process endpoint. One type of known endpoint detection technique involves using reflected incident light to determine the thickness of a film on a wafer during the CMP process.

Optical endpoint detection technique typically uses a transparent window or slit located within a polishing pad that enables incident light to pass through it. The window or slit can be positioned within the polishing pad such that the wafer passes over it every time the polishing pad makes a complete rotation. As the wafer passes over window or slit, incident light shines through window or slit and reflects off of different surfaces within the wafer. A single wavelength or different wavelengths of reflected incident light are then used to determine the thickness of a film on the wafer during the, CMP process. Once the wafer achieves a desired thickness, the CMP process is discontinued.

The manufacture of magnetic recording heads for use in disc drives usually involves patterning a permalloy or copper structure on a base layer, depositing an oxide overfill material, and planarizing the oxide overfill material until it is substantially planar, and the underlying metal pattern is exposed and cleared of the oxide overfill material. The clearing of the oxide overfill material is critical because any remnant oxide would lead to an open path in the electrical or magnetic flux conduction paths. However, the CMP planarization process must be stopped at the correct time to obtain the desired structure.

Where the optical properties of the materials being processed cannot be used to provide an adequate optical signal, the combination of motor current signal changes and optical signal intensity changes may not be able to adequately identify the endpoint.

There is a need for a method that provides more accurate endpoint detection during a chemical mechanical polishing (CMP) process.

### SUMMARY OF THE INVENTION

This invention provides a method of chemical mechanical polishing a wafer comprising: forming an optical property modifying layer on a surface of a feature of interest disposed on a wafer, removing material from the wafer using a chemical mechanical polishing process, directing light onto a surface of the wafer and using light reflected from a surface of the wafer to determine when the optical property modifying layer has been reached, and stopping the chemical mechanical polishing process in response to the determination that the optical property modifying layer has been reached.

The optical property modifying layer can comprise a layer of a material which is optically different from the material of the feature.

In another aspect, the invention encompasses a wafer for use in manufacturing a magnetic recording head, the wafer comprising a substrate, a pattern including an optical property modifying layer on a surface of a feature of interest supported by the substrate, and a dielectric layer positioned on the optical property modifying layer.

### BRIEF DESCRIPTION OF THE DRAWINGS

FIG. 1 is a functional block diagram of a chemical mechanical polishing system.

FIG. 2 is a schematic representation of a portion of an intermediate structure used in the manufacture of a magnetic recording head.

FIG. 3 is a graph showing various parameters that can be monitored during a CMP process.

FIG. 4 is a schematic representation of a portion of another intermediate structure used in the manufacture of a magnetic recording head.

FIG. 5 is a graph showing various parameters that can be monitored during a CMP process.

FIG. 6 is a schematic representation of a portion of another intermediate structure used in the manufacture of a magnetic recording head.

FIG. 7 is a graph showing various parameters that can be monitored during a CMP process.

FIG. 8 is a schematic representation of a portion of another intermediate structure used in the manufacture of a magnetic recording head.

FIG. 9 is a graph showing an optical signal for endpoints on Cu and NiFe structures.

### DETAILED DESCRIPTION OF THE INVENTION

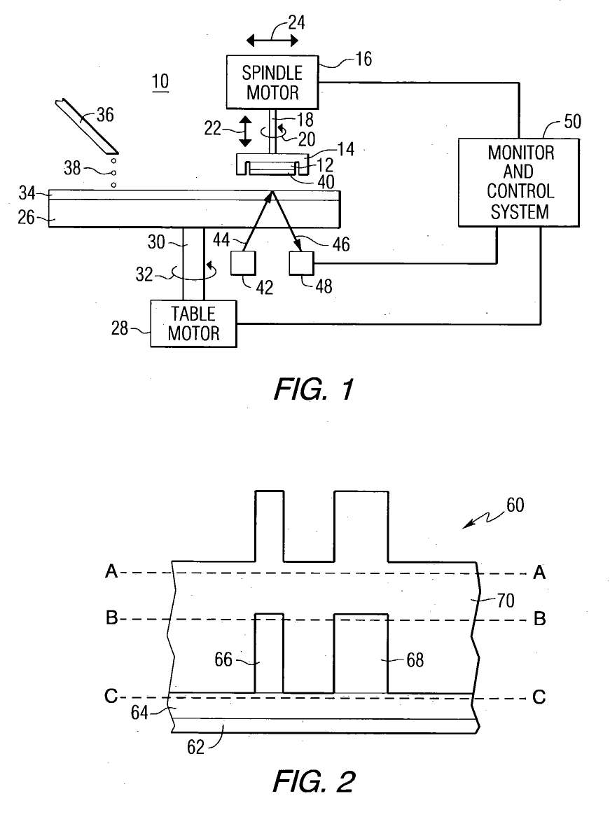

This invention provides a method for improving the detection of a CMP process endpoint. FIG. 1 is a functional block diagram of a chemical mechanical polishing system 10. A wafer 12 that is to be polished is inserted in a wafer carrier 14 that is coupled to a spindle motor 16 by a shaft 18. The wafer carrier can be rotated as indicated by arrow 20, and can be moved vertically and horizontally as indicated by arrows 22 and 24. A polishing table, or platen, 26 is coupled to a table motor 28 by a shaft 30. The platen can be rotated as indicated by arrow 32. A polishing pad 34 is mounted on the platen. A slurry dispensing means 36 is provided for depositing a slurry 38 onto the polishing pad.

Polishing pad 34 can be made of a resilient material such as polyurethane or foam, and can be textured to aid the polishing process. Polishing pad 34 rotates on the platen 26 at a predetermined speed. In the CMP process, the wafer 12 is held in place on the polishing pad. The front surface 40, also called the active surface, of wafer 12 rests against polishing pad 34. As the polishing pad rotates, shaft 18 rotates the wafer 12 at a predetermined rate. Shaft 18 forces wafer 12 into polishing pad 34 with a predetermined amount of downward force. The wafer can also move in a radial direction with respect to the platen.

A light source 42 is provided to produce light as indicated by arrow 44. The light passes through the platen and polishing pad and is reflected by the active surface of the wafer, as indicated by arrow 46. A sensor 48 provides a signal representative of the intensity or some other characteristic of the reflected light. A monitor and control system 50 receives the signal from the sensor. Additional signals that are representative of the current in the platen drive motor 28 and the spindle motor 16 can also be received by the monitor and control system. The monitor and control system can display the received signals and/or process the received signals to determine when the desired endpoint has been achieved.

The slurry can be a mixture of deionized water and polishing agents designed to chemically aid the smooth and predictable planarization of wafer 12. The rotating action of both polishing pad 34 and wafer 12, in conjunction with the polishing action of the slurry, combine to planarize, or polish, wafer 12 at some nominal rate. This rate is referred to as the removal rate. A constant and predictable removal rate is important to the uniformity and throughput performance of the wafer fabrication process. The removal rate should be expedient, yet yield precisely planarized wafers, free from surface anomalies. If the removal rate is too slow, the number of planarized wafers produced in a given period of time decreases, hurting the throughput of the fabrication process. If the removal rate is too fast, the CMP planarization process will not be consistent across several wafers in a batch, thereby hurting the consistency of the fabrication process.

The method uses a signal representative of light reflected by the active surface of the wafer. More specifically, the present invention improves chemical mechanical polishing endpoint detection by creating an optically modifying layer on surfaces of selected features of a pattern on a wafer. The optically modifying layer substantially changes the amount of light reflected by the component. Thus the optically modifying layer can be easily detected and the chemical mechanical polishing process can be stopped on response to the detection of the optically modifying layer.

Furthermore, by precisely controlling the thickness of the optically modified layer, information about the rate of advancement of the planarization front can be obtained. This, in turn, can be used to improve the accuracy of process endpointing.

FIG. 2 is a schematic representation of a portion of a potion of a wafer 60 used in the manufacture of a magnetic recording head. The wafer includes a substrate 62, which may be for example AlTiC, having deposited thereon a basecoat 64, which may be a dielectric material. In this example, a pattern including features 66 and 68, also referred to as ridges, lands or hills, has been plated or otherwise deposited on the basecoat. The pattern can be made of, for example NiFe. A layer of insulating material, such as alumina (Al₂O₃), 70 is deposited on the pattern.

During the course of CMP, the planarization front moves through the plane designated as A-A, and continues downward until it hits the features of interest. The planarization front can be stopped when it reaches the plane designated as B-B, after exposing the NiFe feature. If CMP were not stopped at plane B-B, it could continue to plane C-C.

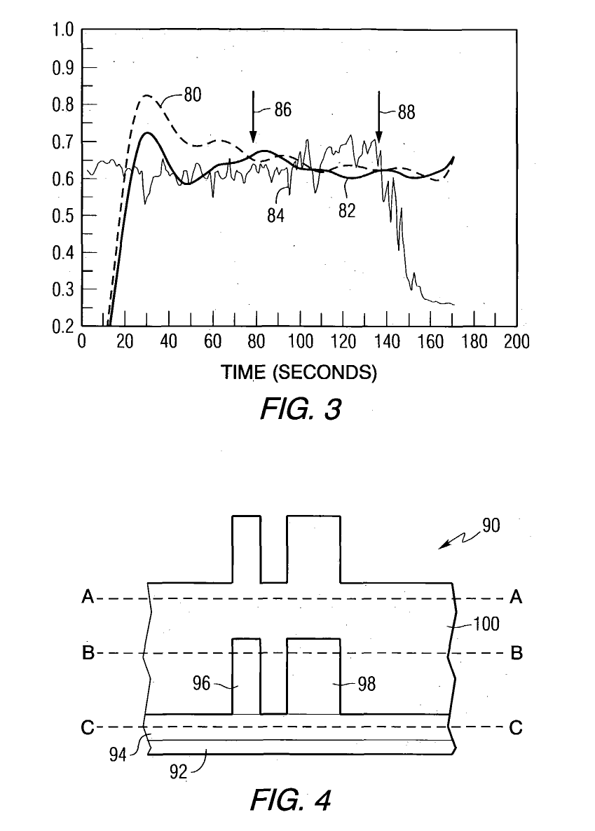

The process is monitored using motor current signals and an optical endpoint signal. FIG. 3 shows the spindle motor current as curve 80, the platen motor current as curve 82, and the optical signal as curve 84. The actual point of the transition across plane B-B is shown by arrow 86 and the actual point of the transition across plane C-C is shown by arrow 88 in FIG. 3. The desired endpoint of the process is the transition from unpolished NiFe features to polished NiFe features, which corresponds to arrow 86. It can be seen that the motor current and optical endpoint signals do not give sufficient indication of the desired endpoint of the process. The result is that the wafer planarization process is unable to be stopped at the right thickness.

A similar outcome is seen for the polishing of sputtered patterned copper structures, filled in with an alumina overfill material and then planarized. FIG. 4 is a schematic representation of a portion of a potion of a wafer 90 that includes patterned copper features. The wafer includes a substrate 92, which may be for example AlTiC, having deposited thereon a basecoat 94, which may be a dielectric material. In this example, a pattern including copper features 96 and 98, also referred to as ridges, lands or hills, has been plated or otherwise deposited on the basecoat. A layer of insulating material, such as alumina (Al₂O₃), 100 is deposited on the pattern.

During the course of CMP, the planarization front moves through the plane designated as A-A, and continues downward until it hits the features. The planarization front can be stopped when it reaches the plane designated as B-B, after exposing the Cu feature. If CMP were not stopped at plane B-B, it could continue to plane C-C.

Still referring to the structure shown in FIG. 4, the oxide overfill material is polished until it is substantially planar and until the underlying metal pattern is fully opened up and cleared of the oxide overfill material. The clearing of the oxide overfill material is critical because any remnant oxide over the copper would lead to an open path in the electrical conduction paths. Likewise, too much of planarization would lead to significant reduction in the height of the copper features.

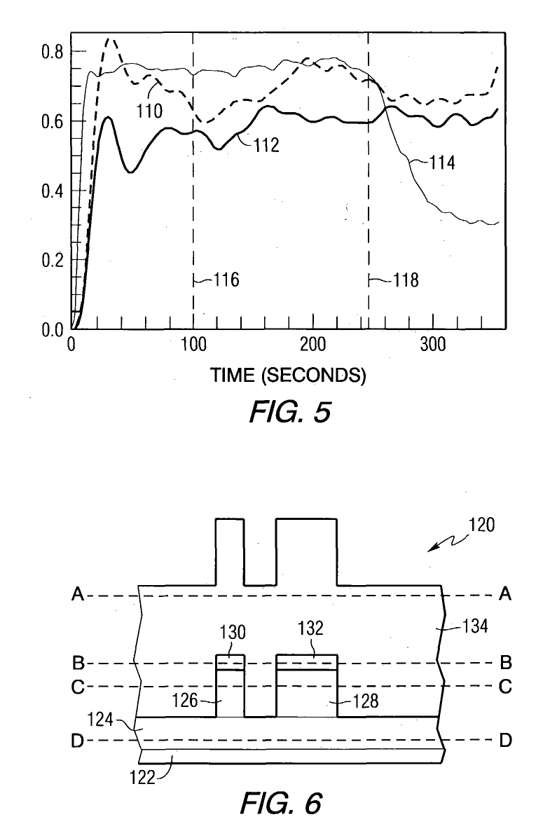

The process is monitored using motor current signals and an optical endpoint signal. FIG. 5 shows the spindle motor current as curve 110, the platen motor current as curve 112, and the optical signal as curve 114. The actual point of the transition across plane B-B is shown by line 116 and the actual point of the transition across plane C-C is shown by line 118 in FIG. 5. The desired endpoint of the process is the transition from unpolished Cu features to polished Cu features, as shown by time corresponding to line 116. It can be seen from FIG. 5, that the motor current and optical endpoint signals do not give sufficient indication of the desired endpoint of the process. The result is that the wafer planarization process is unable to be stopped at the right thickness. This is because the optical property of the surface does not change significantly during planarization.

The present invention provides a solution to the lack of a definitive optical endpoint signal when planarizing metal features overfilled with oxide. In this invention, an optical property modifying means is provided adjacent to a surface of a feature of interest. The optical property modifying means can be, for example, a thin layer of material with substantially different optical properties that is positioned over the surface of a feature of interest. This layer is referred to as the optical property modifier layer (OPML). OPMLs are used to accurately detect endpoint.

FIG. 6 is a schematic representation of a portion of an intermediate structure 120 used in the manufacture of a magnetic recording head that is fabricated in accordance with this invention. The wafer includes a substrate 122, which may be for example AlTiC, having deposited thereon a basecoat 124, which may be a dielectric material. In this example, a pattern including features 126 and 128, also referred to as ridges, lands or hills, has been plated or otherwise deposited on the basecoat. The pattern in this example is made of copper. Optical property modifying layers 130 and 132 are made of NiFe and are positioned on the tops of features 126 and 128 respectively, and serve as the OPML. A layer of insulating material, such as alumina (Al₂O₃), 134 is deposited over the pattern comprising layers 126, 128, 130 and 132. For the case of a copper feature with overfilled alumina, a thin layer of NiFe can be positioned on the top surface of the copper as the OPML to reliably detect process endpoint.

During the course of CMP, the planarization front moves through the plane designated as A-A, and continues downward through the optically modifying layers 130 and 132, positioned in plane B-B. After exposing the metal features, the planarization front would stop at plane C-C. If CMP were not stopped at plane C-C, it could continue to plane D-D.

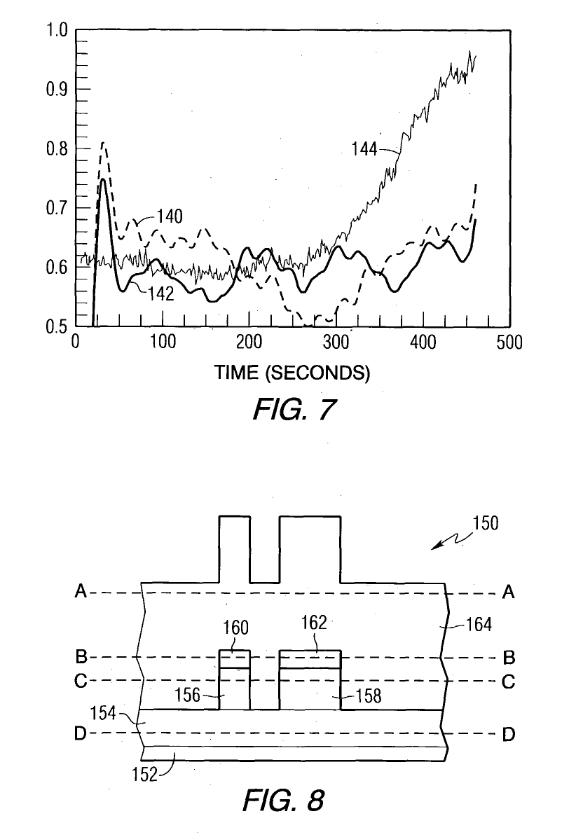

The process for the structure of FIG. 6 has been monitored using motor current signals and an optical endpoint signal. FIG. 7 shows the spindle motor current as curve 140, the platen motor current as curve 142, and the optical signal as curve 144. In this case, the endpoint transition to top surfaces of the copper features would be clearly demarcated, as shown by the endpoint trace 144 in FIG. 7, which shows a clear transition when the copper is broken through from the NiFe on top. The endpoint can be determined by changes in the optical signal as the planarization front transitions from the OPML into the features of interest.

In the case of the NiFe feature with overfilled alumina, a thin layer of copper can be used as the OPML. FIG. 8 is a schematic representation of a portion of an intermediate structure 150 used in the manufacture of a magnetic recording head that is fabricated in accordance with this invention. The wafer includes a substrate 152, which may be for example AlTiC, having deposited thereon a basecoat 154, which may be a dielectric material. In this example, a pattern including features 156 and 158, also referred to as ridges, lands or hills, has been plated or otherwise deposited on the basecoat. The pattern in this example is made of NiFe. Optical property modifying layers 160 and 162 of copper are positioned on the tops of features 156 and 158 respectively. A layer of insulating material, such as alumina (Al₂O₃), 164 is deposited on top of the patterned OPML.

During the course of CMP, the planarization front moves through the plane designated as A-A, and continues downward through the optically modifying layers 162 and 164, positioned in plane B-B. After exposing the metal features, the planarization front would stop at plane C-C. If CMP were not stopped at plane C-C, it could continue to plane D-D.

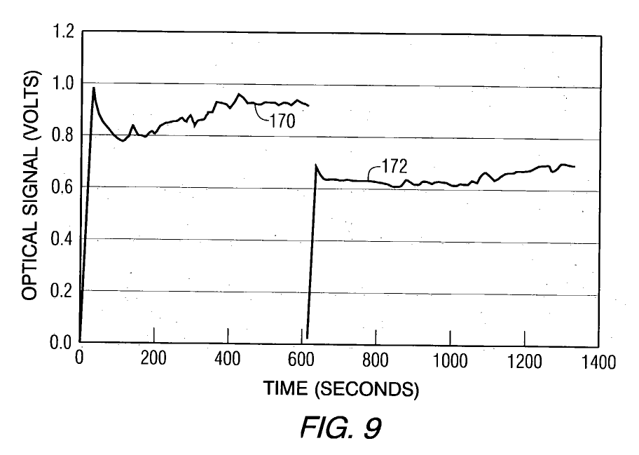

FIG. 9 is a graph showing the optical signal for copper as shown by curve 170 and for NiFe as shown by curve 172. This shows a clear difference in the optical signals for these materials.

Even though the examples use NiFe and Cu as the exemplary magnetic material and conductor for the processing of read-write heads, it is understood that other magnetic materials and conductors are also amenable to the teachings of this invention. For example, the magnetic material may be made of other alloys such as Co,NiFe, FeCo, CoNi, FeCoX (where X denotes a ternary metal). Likewise, the metal could be Tantalum, Cu, Ag, Au, etc.

The OPML modifies the surface optical properties of the top of the metal patterned structure so as to effectively provide a reliable endpoint signal. The surface OPML can be formed by a variety of techniques. For example, the OPML could be a “dusting layer” of a material which is optically different from the material under it.

The OPML could also be formed by the oxidation of the metal surface so as to form a surface with different optical properties than the bulk of the metal pattern under it. When the planarization front cuts through the surface, it removes the surface layer and exposes the bulk material, causing the signal to change significantly.

The OPML can alternatively be formed as a small/thin tarnish layer. For example, copper tarnishes to a dullish brown appearance, and thus, when tarnished Cu is used to determine the endpoint, a jump in the optical signal will be observed at the CMP endpoint. For the case of NiFe, it tarnishes to a yellow film. When it is planarized, it reverts to a shiny silvery finish. When tarnished NiFe is used to detect the endpoint, a strong change in the optical signal will be observed.

Other carbides and nitrides and oxide materials can also be used as the OPML. Other surface treatments on the top of the metal pattern surface may also be applicable. Such examples include phosphate and zincate processes. In the case of phosphating, the initial pattern could be immersed, for example, in an appropriate temperature controlled solution of phosphoric acid and a mixture of sodium and ammonium dihydrogen phosphates, or zinc dihydrogen phosphate to form a phosphate coating as an OPML layer on the surface, which would have significantly different optical reflection properties compared to the base metal underlying it. In the case of zincating process, the metal pattern could be immersed in a bath comprising of a mixture of zinc oxide and sodium hydroxide, forming a layer of zinc with different optical properties on the underlying metal pattern.

If the metal features are plated, a nodular morphology can be created at the top surfaces of the features of interest. The nodular surface will have optical properties that differ from a polished surface. In addition, any other process that causes the surface optical property to change can be used in this invention as long as it effectively enables CMP process endpoint detection. Furthermore, materials that respond differentially to radiation of different wavelengths can also serve as effective OPMLs. Examples are fluorescent materials and phosphorescent materials.

In the fabrication of magnetic recording heads, the features of interest can range in height from 50 Å to 3000 μm. The thickness of the OPMLs can range from 50 Å to 1 μm. Generally, the OPML thickness should be sufficient so that it translates to a sufficient signal duration during the CMP process so as to detect the endpoint of the process.

By using the present invention, an operator of a CMP machine can know precisely when to stop a CMP process of a semiconductor wafer. Furthermore, the present invention essentially eliminates excessive chemical mechanical polishing of the semiconductor wafer. Therefore, the present invention is able to reduce fabrication costs of the wafers.

A key advantage is that this technique allows an operator to detect whether the wafer has been planarized to the desired thickness or not in real-time, in-situ. This allows precise control of the position of the planarization front to within 10's of Angstroms. Currently there is no such accurate capability in thin film head manufacturing. One application of the invention is the detection of the endpoint of top pole “breadloaf” planarization for the perpendicular magnetic recording head writer. This is most amenable to the optical endpointing because the structure to be planarized is itself only 5000 Å thick, with a target post CMP thickness of 3000 Å. Lack of planarization of the top pole leads to a curved trailing edge curvature, and to a consequent loss of linear density.

With this invention, a CMP operator can optically monitor small areas in the center, mid diameter, and outer diameter of the wafer and be able to tell with great reliability if the CMP process has been completed. Furthermore, based on the time delays between the transitions between the OPML and the underlying layer signals between the center and the edge of the wafer, feedback action to minimize the center to edge time delay can be implemented and thereby improve the uniformity of the process. Thus, use of this technique would lead to decreased process cycle time, increased yield and process reliability.

In the manufacture of electronic devices, numerous devices can be formed on a single wafer and simultaneously process using CMP. In order to increase the optical signal, dummy devices having OPMLs with thickness cross-section profiles similar to those of the actual devices can be added to the wafer, thereby increasing the total surface area of the OPMLs that contributes to the reflected light.

Stoppage of the CMP can be directly or indirectly in response to the detection of the OPML. For example, in some cases CMP might be stopped when the OPML is detected. In other cases, CMP might be stopped after a predetermined time period following detection of the OPML. If the removal rate is known, the location of the planarization front can be determined based on the time interval following detection of the OPML.

While the present invention has been described in terms of particular examples, it will be apparent to those skilled in the art that various changes can be made to the disclosed examples without departing from the scope of the invention as set forth in the following claims. For example, the method can be used for planarizing surfaces of various components such as semiconductor devices and/or conductor interconnection wiring patterns.

What is claimed is:

1. A method of chemical mechanical polishing a wafer, the method comprising:
forming an optical property modifying layer on a surface of a feature of interest disposed on a wafer;
removing material from the wafer using a chemical mechanical polishing process;
directing light onto a surface of the wafer and using light reflected from a surface of the wafer to determine when the optical property modifying layer has been reached; and
stopping the chemical mechanical polishing process in response to the determination that the optical property modifying layer has been reached.

2. The method of claim 1, wherein the optical property modifying layer comprises:
a layer of a material which is optically different from the material of the feature.

3. The method of claim 1, wherein the optical property modifying layer comprises:
an oxide of the material of the feature.

4. The method of claim 1, wherein the optical property modifying layer comprises:
a tarnish layer.

5. The method of claim 1, wherein the optical property modifying layer comprises:
a material that responds differentially to radiation of different wavelengths.

6. The method of claim 1, wherein the optical property modifying layer has a thickness ranging from 50 Å to 1 μm.

7. The method of claim 1, further comprising:
depositing a dielectric layer over the optical property modifying layer, wherein said dielectric layer comprises an oxide.

8. The method of claim 1, wherein the feature of interest comprises one of: Cu or NiFe.

9. The method of claim 8, wherein the feature of interest comprises NiFe and the optical property modifying layer comprises copper.

10. The method of claim 8, wherein the feature of interest comprises Cu and the optical property modifying layer comprises NiFe.

11. The method of claim 1, further comprising:
forming optical property modifying layers of different thicknesses and using the thicknesses to self-calibrate the process and improve endpoint accuracy.

12. The method of claim 1, wherein the optical modifying layer comprises a material selected from the group consisting of. CoNiFe, FeCo, and FeCo-alloys.

13. The method of claim 1, wherein the optical modifying layer is formed using a zincating or phosphating process.

14. The method of claim 1, further comprising:
using optical endpoint dummy structures on the wafer to improve signal/noise ratio of the optical signal.

15. A wafer for use in manufacturing a magnetic recording head, the wafer comprising:
a substrate;
a pattern including an optical property modifying layer on a surface of a feature of interest supported by the substrate; and
a dielectric layer positioned on the optical property modifying layer.

16. The wafer of claim 15, wherein the optical property modifying layer comprises:
a layer of a material which is optically different from the material of the feature.

17. The wafer of claim 15, wherein the optical property modifying layer comprises:
an oxide of the material of the feature.

18. The wafer of claim 15, wherein the optical property modifying layer comprises:
a tarnish layer.

19. The wafer of claim 15, wherein the optical property modifying layer comprises:
a material that responds differentially to radiation of different wavelengths.

20. The wafer of claim 15, wherein the optical property modifying layer has a thickness ranging from 50 Å to 1 μm.

21. The wafer of claim 15, further comprising:
depositing a dielectric layer over the optical property modifying layer, wherein said dielectric layer comprises an oxide.

22. The wafer of claim 15, wherein the feature of interest comprises one of: Cu or NiFe.

23. The wafer of claim 22, wherein the metal comprises NiFe and the optical property modifying layer comprises copper.

24. The wafer of claim 22, wherein the metal comprises Cu and the optical property modifying layer comprises NiFe.

25. The wafer of claim 15, wherein the optical modifying layer comprises a material selected form the group consisting of: CoNiFe, FeCo, and FeCo-alloys.

26. The wafer of claim 15, wherein the optical modifying layer is formed using a zincating or phosphating process.

27. The wafer of claim 15, further comprising:
optical endpoint dummy structures on the wafer.
